(19) United States
(12) Patent Application Publication
(10) Pub. No.: US 2026/0290772 A1
(43) Pub. Date: Sep. 24, 2026

(54) SPUTTERING APPARATUS

(71) Applicant: Tokyo Electron Limited, Tokyo (JP)

(72) Inventors: Hiromu INOUE, Fuchu City (JP); Naoya FUKUDA, Fuchu City (JP)

(21) Appl. No.: 19/562,019

(22) Filed: Mar. 10, 2026

(30) Foreign Application Priority Data
Mar. 19, 2025 (JP) 2025-044393

(51) Int. Cl. H01J 37/34; C23C 14/34; C23C 14/35

(52) U.S. Cl. CPC H01J 37/3455; C23C 14/3407; C23C 14/35; H01J 37/3408

(57) ABSTRACT

A sputtering apparatus includes: a processing container; a substrate stage configured to place a substrate thereon inside the processing container; a cathode unit having a target disposed above the substrate; a radio-frequency power supply configured to supply radio-frequency power to the target; a magnet unit including a magnet fixing portion provided on a rear side of the target to fix a magnet, and a rocking drive configured to move the magnet fixing portion; and a covering member configured to cover a rear side of the cathode unit and a rear side of the magnet fixing portion, wherein the rocking drive includes a motor disposed outside the covering member and configured to rock the magnet fixing portion.

### CROSS-REFERENCE TO RELATED APPLICATION

This application is based upon and claims the benefit of priority from Japanese Patent Application No. 2025-044393, filed on Mar. 19, 2025, the entire contents of which are incorporated herein by reference.

### TECHNICAL FIELD

The present disclosure relates to a sputtering apparatus.

### BACKGROUND

Patent Document 1 discloses a sputtering apparatus including a processing chamber, a cathode on which a target is capable of being mounted on a side where a workpiece is disposed, and a magnet device that is located on a side opposite to the side where the target of the cathode is mounted and that forms a magnetic field on a surface of the target. Patent Document 1 also discloses that the magnet device is a magnet device that forms a point cusped magnetic field and that the magnet device is connected to a rotation mechanism for rotating a magnet array in an in-plane direction around a central axis of a target member.

Patent Document 2 discloses a film formation apparatus including a target for emitting sputtering particles toward a substrate, a magnet provided on a rear side of the target to apply a leakage magnetic field to the target, and a magnet drive for driving the magnet. Patent Document 2 also discloses that the magnet drive includes a rocking drive that rocks the magnet along the target.

Patent Document 3 discloses a sputtering film formation apparatus including a target support having a target supporting surface for supporting a target, and a magnetron magnetic circuit located on a side facing the target supporting surface. Patent Document 3 also discloses that the sputtering film formation apparatus includes a first rocking mechanism that rocks a magnetron magnetic circuit in a first direction in a plane of the target supporting surface, and a second rocking mechanism that rocks the magnetron magnetic circuit in a second direction different from the first direction.

### Prior Art Documents

### Patent Documents

Patent Document 1: Japanese Patent No. 4763857

Patent Document 2: Japanese Patent No. 7374008

Patent Document 3: Japanese Laid-Open Patent Publication No. 2011-137205

### SUMMARY

According to one embodiment of the present disclosure, a sputtering apparatus includes: a processing container; a substrate stage configured to place a substrate thereon inside the processing container; a cathode unit having a target disposed above the substrate; a radio-frequency power supply configured to supply radio-frequency power to the target; a magnet unit including a magnet fixing portion provided on a rear side of the target to fix a magnet, and a rocking drive configured to move the magnet fixing portion; and a covering member configured to cover a rear side of the cathode unit and a rear side of the magnet fixing portion, wherein the rocking drive includes a motor disposed outside the covering member and configured to rock the magnet fixing portion.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating an outline of a sputtering apparatus according to an embodiment of the present disclosure.

FIG. 2 is a diagram illustrating the outline of the sputtering apparatus according to the embodiment of the present disclosure.

FIG. 3 is a diagram for explaining an arrangement and movement of magnets of a magnet unit in the sputtering apparatus according to the embodiment of the present disclosure.

### DETAILED DESCRIPTION

Hereinafter, an embodiment will be described with reference to the accompanying drawings. The present disclosure is not limited to the illustrated embodiment, but is intended to be defined by the appended claims and to encompass all modifications and variations falling within the meaning and scope equivalent to the appended claims. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the specification and drawings, substantially same or corresponding constituent elements are denoted by same or corresponding reference numerals, and redundant descriptions thereof may be omitted. In order to facilitate understanding, the scale of each part in the drawings may differ from the actual scale.

A sputtering apparatus according to an embodiment will now be described. The sputtering apparatus according to this embodiment includes a processing container, a substrate stage configured to place a substrate thereon inside the processing container, a cathode unit having a target disposed above the substrate, and a radio-frequency power supply configured to supply radio-frequency power to the target. Further, the sputtering apparatus according to the embodiment is provided with a magnet unit including a magnet fixing portion provided on a rear side of the target to fix a magnet, and a rocking drive configured to move the magnet fixing portion. Further, the sputtering apparatus according to the embodiment include a covering member configured to cover a rear side of the cathode unit and a rear side of the magnet fixing portion. In the sputtering apparatus according to the embodiment, the rocking drive of the magnet unit includes a motor disposed outside the covering member to rock the magnet fixing portion.

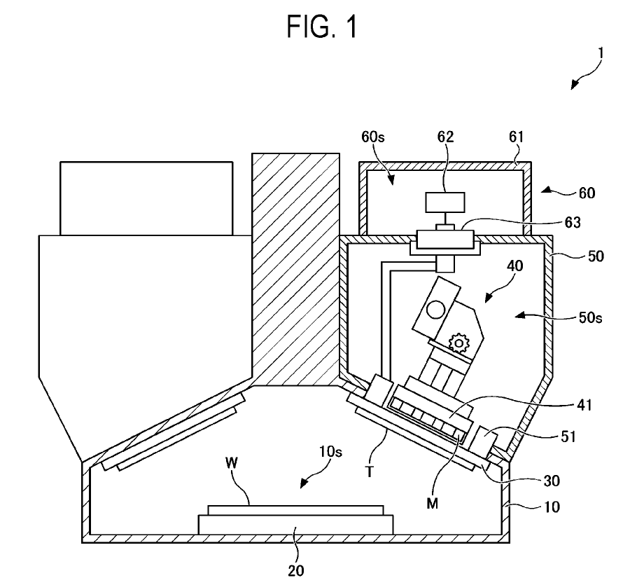

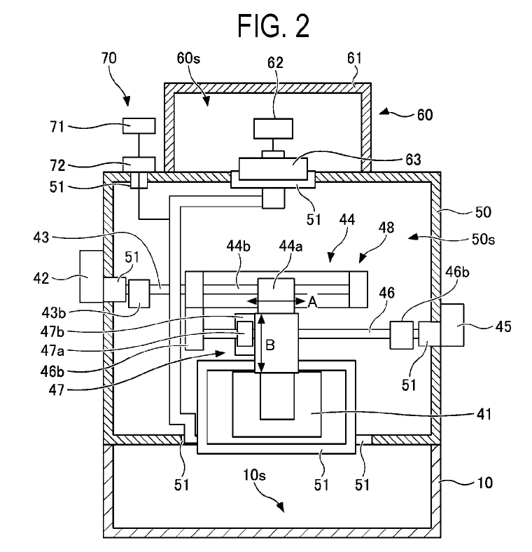

Details of the sputtering apparatus according to the embodiment will now be described with reference to the drawings. FIGS. 1 and 2 are diagrams illustrating an outline of a sputtering apparatus 1, which is an example of the sputtering apparatus according to the embodiment.

The sputtering apparatus 1 forms a thin film of a material contained in a target T on a substrate W by causing particles to collide with the target T and depositing the particles of the target T on the substrate W. The sputtering apparatus 1 includes a processing container 10, a substrate stage 20, a cathode unit 30, a magnet unit 40, a covering member 50, a radio-frequency circuit 60, and a direct-current circuit 70.

The processing container 10 accommodates the substrate stage 20 in an internal space 10s thereof. The processing container 10 is, for example, a vacuum chamber. When the substrate W is processed, the internal space 10s of the processing container 10 is maintained in, for example, a vacuum state.

The substrate W is placed on the substrate stage 20. The substrate stage 20 includes, for example, an electrostatic chuck. The substrate stage 20 is provided inside the processing container 10 to face the cathode unit 30.

The cathode unit 30 holds the target T. Radio-frequency power from the radio-frequency circuit 60 is supplied to the cathode unit 30. In addition, direct-current power from the direct-current circuit 70 is supplied to the cathode unit 30.

The magnet unit 40 holds a plurality of magnets M. Further, the magnet unit 40 moves the plurality of magnets M along the target T. The magnet unit 40 includes a magnet fixing portion 41 to which the plurality of magnets M is fixed, and a rocking drive 48 that moves the magnet fixing portion 41 along the target T.

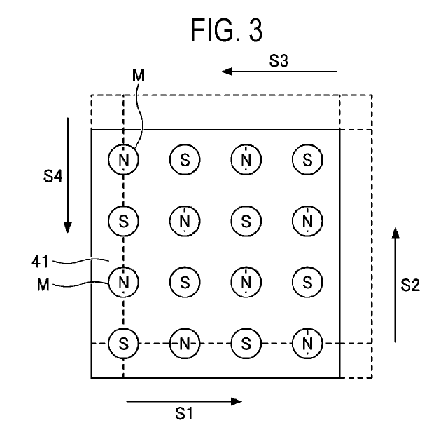

The magnet fixing portion 41 holds the plurality of magnets M such that, for example, polarities of adjacent magnets M are reversed. FIG. 3 is a diagram for explaining an arrangement and movement of the magnets M of the magnet unit 40 in the sputtering apparatus 1, which is an example of the sputtering apparatus according to the embodiment. In FIG. 3, N and S indicate magnetic polarities of the magnets M. As shown in FIG. 3, the plurality of magnets M is arranged such that magnetic polarities N and S of the magnets M arranged horizontally or vertically in FIG. 3 are reversed. The plurality of magnets M is arranged in a grid pattern. For example, the plurality of magnets M is arranged in a square grid pattern or a rectangular grid pattern. By arranging the plurality of magnets M in the grid pattern such that the magnetic poles thereof are opposite to each other, the magnet unit 40 generates a point cusped magnetic field to be directed toward the target T in the cathode unit 30.

The rocking drive 48 moves the magnet fixing portion 41 along the target T. The rocking drive 48 includes a motor 42, a rotary shaft 43, a ball screw mechanism 44, a motor 45, a rotary shaft 46, and a rack pinion mechanism 47.

The motor 42 rotates the rotary shaft 43. The motor 42 is provided outside the covering member 50. The rocking drive 48 may include a mechanism, for example, a miter gear, for switching a rotation direction between the motor 42 and the rotary shaft 43.

The rotary shaft 43 is rotated by the motor 42. The rotary shaft 43 is connected to a screw shaft 44b of the ball screw mechanism 44. When the rotary shaft 43 is rotated by the motor 42, the screw shaft 44b of the ball screw mechanism 44 is rotated. The rotary shaft 43 is supported by a bearing 43b. The bearing 43b is disposed so as to be insulated from the processing container 10 or the covering member 50 by an insulating material. By insulating the bearing 43b from the processing container 10 or the covering member 50, the radio-frequency power transmitted to the motor 42 via the rotary shaft 43 is blocked.

The ball screw mechanism 44 converts rotational motion of the rotary shaft 43 into linear motion in a direction parallel to the target T. The ball screw mechanism 44 includes a movement portion 44a and the screw shaft 44b. The movement portion 44a includes a nut which is engaged with the screw shaft 44b via a ball. The movement portion 44a is connected to the magnet fixing portion 41. As the movement portion 44a moves, the magnet fixing portion 41 moves in a direction indicated by arrow A.

The motor 45 rotates the rotary shaft 46. The motor 45 is provided outside the covering member 50. The rocking drive 48 may include a mechanism, for example, a miter gear, which is disposed between the motor 45 and the rotary shaft 46 to change a rotational direction.

The rotary shaft 46 is rotated by the motor 45. The rotary shaft 46 is connected to a pinion gear 47a of the rack pinion mechanism 47. When the rotary shaft 46 is rotated by the motor 45, the pinion gear 47a of the rack pinion mechanism 47 is rotated. The rotary shaft 46 is supported by a bearing 46b. The bearing 46b is disposed so as to be insulated from the processing container 10 or the covering member 50 by an insulating material. By insulating the bearing 46b from the processing container 10 or the covering member 50, the radio-frequency power transmitted to the motor 45 via the rotary shaft 46 is blocked.

The rack pinion mechanism 47 converts rotational motion of the rotary shaft 46 into linear motion in a direction parallel to the target T. The rack pinion mechanism 47 includes the pinion gear 47a and a rack gear 47b. The rack gear 47b is connected to the magnet fixing portion 41. When the pinion gear 47a rotates, the rack gear 47b moves in a direction indicated by arrow B. As the rack gear 47b moves, the magnet fixing portion 41 moves in the direction indicated by arrow B.

By using the rocking drive 48, the sputtering apparatus 1 may rock the plurality of magnets M in, for example, a biaxial direction as shown in FIG. 3. For example, in FIG. 3, by moving the plurality of magnets M fixed to the magnet fixing portion 41 in order of arrow S1, arrow S2, arrow S3, and arrow S4, biaxial rocking may be implemented. The rocking drive 48 moves the magnet fixing portion 41 to, for example, an intermediate position between adjacent magnets M. As the rocking drive 48 moves the magnet fixing portion 41 to the intermediate position between adjacent magnets M, portions of the target T that are not consumed during uniaxial rocking may be consumed.

The covering member 50 covers a side (rear side) of the cathode unit 30, which is opposite to the target T. Further, the covering member 50 covers a side (rear side) of the magnet fixing portion 41 of the magnet unit 40, which is opposite to the target T. The covering member 50 has an internal space 50s. A portion of the magnet unit 40 is accommodated in the internal space 50s. The covering member 50 is formed of a conductive member, for example, a metal. In the magnet unit 40, the motor 42 and the motor 45 are disposed outside the covering member 50.

The radio-frequency circuit 60 supplies the radio-frequency power to the cathode unit 30. The radio-frequency circuit 60 includes a cover 61, a radio-frequency power supply 62, and a matching circuit 63. The cover 61 houses the radio-frequency power supply 62 in an internal space 60s. The cover 61 functions as a shield.

Each of the radio-frequency power supply 62 and the matching circuit 63 is disposed outside the covering member 50. The radio-frequency power supply 62 supplies radio-frequency power for performing RF etching to the cathode unit 30. The matching circuit 63 outputs the radio-frequency power input from the radio-frequency power supply 62 to the target T of the cathode unit 30. The matching circuit 63 is configured to match an impedance of the radio-frequency power supplied from the radio-frequency power supply 62. The matching circuit 63 is connected to the internal space 50s of the covering member 50 via an insulating member 51.

The direct-current circuit 70 supplies the direct-current power to the cathode unit 30. The direct-current circuit 70 includes a direct-current power supply 71 and a filter circuit 72. Each of the direct-current power supply 71 and the filter circuit 72 is disposed outside the covering member 50. The direct-current power supply 71 supplies direct-current power to the cathode unit 30. The filter circuit 72 outputs the direct-current power input from the direct-current power supply 71 to the target T of the cathode unit 30. The filter circuit 72 is a low-pass filter. The filter circuit 72, which is the low-pass filter, prevents backflow of the radio-frequency power to the direct-current power supply 71. The filter circuit 72 is connected to the internal space 50s of the covering member 50 via the insulating member 51.

When RF sputtering is executed, the internal space 10s, the internal space 50s, and the internal space 60s are kept in a radio-frequency environment. In the magnet unit 40, the motors 42 and 45, which are electric-powered components, are provided outside the covering member 50, that is, outside the radio-frequency environment. By disposing the motors 42 and 45 outside the radio-frequency environment, it is possible to suppress an influence of a malfunction due to a radio frequency.

Each of the cathode unit 30, the motor 42, the motor 45, the matching circuit 63, and the filter circuit 72 is connected to the internal space 50s via the insulating member 51. By connecting each of the cathode unit 30, the motor 42, the motor 45, the matching circuit 63, and the filter circuit 72 to the internal space 50s via the insulating member 51, it is possible to suppress the influence due to the radio frequency.

According to the sputtering apparatus of the embodiment, the motor of the rocking drive that moves the magnets is disposed outside the covering member, which makes it possible to suppress the motor from being influenced by the radio-frequency power. According to the sputtering apparatus of the embodiment, by suppressing the motor from being influenced by the radio-frequency power, it is possible to stably rock the magnets.

RF sputtering uses a radio-frequency alternating-current power supply. By using the radio-frequency alternating-current power supply, a voltage applied to the target alternates. As the voltage applied to the target alternates, both positive ions and electrons may be drawn toward the substrate by the RF sputtering. In addition, as the voltage applied to the target alternates, an insulating target may be continuously sputtered without causing charge-up by the RF sputtering. For example, in DC(direct-current) sputtering, a direct-current voltage is applied to continuously draw positive ions. Thus, an insulator may be charged positively (charged-up), which makes it difficult to use an insulating material as the target.

In recent years, there is a case in which the RF sputtering is employed for the purpose of sputtering the insulating target and improving the efficiency of sputtering itself. The RF sputterer needs to include a matching circuit (matching unit) in addition to the radio-frequency power supply. Since the radio-frequency power supply and the matching circuit have an adverse influence of electromagnetic compatibility (EMC) noise on peripheral devices, it is necessary to arrange the radio-frequency power supply and the matching circuit as close to the cathode as possible. In addition, it is necessary to take measures to prevent the EMC noise generated from the sputtering apparatus from affecting the peripheral devices.

The sputtering apparatus according to the embodiment includes the covering member which covers the rear side of each of the cathode unit and the magnet fixing portion, which makes it possible to prevent the EMC noise generated from the sputtering apparatus from affecting the peripheral devices. In addition, in the sputtering apparatus according to the embodiment, the motor of the rocking drive which moves the magnets is disposed outside the covering member, thereby suppressing the motor from being influenced by the radio-frequency power.

Further, the magnets having a columnar shape are arranged in a grid pattern on the rear side of the target such that the magnetic poles thereof are opposite to each other. This generates the point cusped magnetic field. For example, the magnets may have a cylindrical, elliptic columnar, or polygonal columnar shape. A cusp region of the magnetic field may generate a region with high plasma density in a sputtering space, which makes a sputtering process more efficient.

Further, in the sputtering apparatus, when the target is continuously sputtered at the same location, erosion progresses and the target is locally consumed. Therefore, the magnets are moved relative to the target, that is, the magnets are rocked, so that the target may be uniformly consumed. This reduces the frequency of replacement of the target.

To use the target efficiently, the erosion may be uniformly performed while rocking or rotating the magnets. When the point cusped magnetic field is formed, for example, when the magnets arranged at equal intervals are uniaxially rocked or are rotated, a range in which the target is not consumed occurs within the target. When the point cusped magnetic field is formed, it is desirable to biaxially rock the magnets in order to uniformly consume the target.

In the sputtering apparatus according to the embodiment, the rocking drive includes the ball screw mechanism and the rack pinion mechanism to biaxially rock the magnet fixing portion. According to the sputtering apparatus of the embodiment, the magnet fixing portion is biaxially rocked, which makes it possible to uniformly consume the target.

In addition, the rotary shaft 43 is an example of a first shaft, the rotary shaft 46 is an example of a second shaft, the motor 42 is an example of a first motor, the motor 45 is an example of a second motor, the direction of arrow A is an example of a first direction, and the direction of arrow B is an example of a second direction. The matching circuit 63 is an example of a radio-frequency power introducer, and the filter circuit 72 is an example of a direct-current power introducer.

The present disclosure in some embodiments provides a technique for stably rocking magnets in an RF sputtering apparatus.

The sputtering apparatus according to the embodiment disclosed herein should be considered to be exemplary in all respects and not to be restrictive. The aforementioned embodiments may be modified and improved in various ways without departing from the scope and spirit set forth in the appended claims. The matters described in the aforementioned embodiments may have other configurations to the extent that they are not contradictory, and may be combined to the extent that they are not contradictory.

What is claimed is:

1. A sputtering apparatus, comprising:
a processing container;
a substrate stage configured to place a substrate thereon inside the processing container;
a cathode unit having a target disposed above the substrate;
a radio-frequency power supply configured to supply radio-frequency power to the target;
a magnet unit including a magnet fixing portion provided on a rear side of the target to fix a magnet, and a rocking drive configured to move the magnet fixing portion; and
a covering member configured to cover a rear side of the cathode unit and a rear side of the magnet fixing portion,
wherein the rocking drive includes a motor disposed outside the covering member and configured to rock the magnet fixing portion.

2. The sputtering apparatus of claim 1, wherein the magnet includes a plurality of magnets,
wherein the plurality of magnets is arranged in a grid pattern in the magnet fixing portion such that magnetic poles of the plurality of magnets are opposite to each other.

3. The sputtering apparatus of claim 2, wherein the motor includes a first motor, and
wherein the rocking drive includes a first shaft configured to connect the first motor and the magnet and move the magnet.

4. The sputtering apparatus of claim 3, wherein the first motor is connected to the first shaft via an insulating member.

5. The sputtering apparatus of claim 3, wherein the first shaft moves the magnet in a first direction parallel to the target.

6. The sputtering apparatus of claim 5, wherein the motor further includes a second motor, and
wherein the rocking drive includes a second shaft configured to connect the second motor and the magnet and move the magnet in a second direction different from the first direction.

7. The sputtering apparatus of claim 6, wherein the second motor is connected to the second shaft with an insulating member interposed between the second motor and the second shaft.

8. The sputtering apparatus of claim 6, wherein the first shaft is connected to a screw shaft of a ball screw mechanism, and
wherein the second shaft is connected to a pinion gear of a rack pinion mechanism.

9. The sputtering apparatus of claim 1, further comprising:
a radio-frequency power introducer connected to the rear side of the target and configured to output the radio-frequency power input from the radio-frequency power supply to the target;
a direct-current power supply configured to supply direct-current power to the target; and
a direct-current power introducer connected to the rear side of the target and configured to output the direct-current power input from the direct-current power supply to the target.

10. The sputtering apparatus of claim 9, wherein each of the radio-frequency power supply, the radio-frequency power introducer, the direct-current power supply, and the direct-current power introducer is disposed outside the covering member, and
wherein each of the radio-frequency power introducer and the direct-current power introducer is connected to an internal space of the covering member via an insulating member.

11. The sputtering apparatus of claim 1, wherein the motor includes a first motor, and
wherein the rocking drive includes a first shaft configured to connect the first motor and the magnet and move the magnet.
